(19) United States
(12) Patent Application Publication
(10) Pub. No.: US 2026/0323856 A1
(43) Pub. Date: Oct. 15, 2026

(54) LATCH ASSEMBLY FOR A PLUGGABLE MODULE

(71) Applicant: HEWLETT PACKARD ENTERPRISE DEVELOPMENT LP, Spring, TX (US)

(72) Inventors: Shou-Jen Yang, Taipei City (TW); Chi Wei Cheng, Taipei City (TW); Chi-Ting Yang, Taipei City (TW)

(21) Appl. No.: 19/176,449

(22) Filed: Apr. 11, 2025

(51) Int. Cl. H05K 7/14

(52) U.S. Cl. CPC H05K 7/1401; H05K 7/1485

(57) ABSTRACT

A latch assembly having a cantilever arm and a handle for a pluggable module is disclosed. The cantilever arm includes a beam attached to a sidewall of the pluggable module and a catch protruding from the beam. The catch is configured to engage with or disengage from a catch opening in a chassis to secure or release the pluggable module to/from the chassis. The handle is connected to the cantilever arm such that the handle is movable relative to the sidewall in first or second directions transverse to a longitudinal axis of the cantilever arm to transition the cantilever arm to unlatched or latched states. The handle is configured to convert a longitudinal force applied to the handle and directed parallel to the longitudinal axis into a movement of the handle relative to the sidewall in the first direction to transition the cantilever arm from the latched to unlatched states.

### BACKGROUND

Many information processing devices such as a computer, a networking device, or the like are mounted to a support structure to optimize space, improve airflow, and facilitate maintenance. These support structures may include standardized racks, system chassis of multiple-node systems (e.g., blade systems), or other supports. Generally, operational efficiency of the information processing devices may be enhanced by pluggable modules such as hard drives, power supply units, network interface cards, transceivers, and the like. Pluggable modules are generally designed to be easily installed in and removed from the information processing device from outside the chassis without requiring the use of tools or the opening of the chassis. Further, some of these pluggable modules are hot-swappable pluggable modules that are designed for easy installation and removal from the device without needing to power down the device. Accordingly, users may have quick and easy access to the pluggable modules to perform routine tasks such as maintenance, upgrades, and troubleshooting, as it minimizes device downtime, and allows the users to perform such routine tasks efficiently and safely.

### BRIEF DESCRIPTION OF THE DRAWINGS

Various examples will be described below with reference to the following figures.

FIG. 1A includes a schematic top view of a system having a rack, and an information processing device mounted to support structures of the rack, and having a latch assembly in a latched state to secure a pluggable module to the information processing device according to an example of the present disclosure.

FIG. 1B includes a schematic top view of the system of FIG. 1A having the latch assembly in an unlatched state to release the pluggable module from the information processing device according to an example of the present disclosure.

FIG. 2A includes a perspective view of a cantilever arm of a latch assembly according to an example of the present disclosure.

FIG. 2B includes a perspective view of a handle of a latch assembly according to an example of the present disclosure.

FIG. 2C includes another perspective view of the handle of FIG. 2B according to an example of the present disclosure.

FIG. 2D includes a perspective view of a latch assembly including the cantilever arm of FIG. 2A and the handle of FIGS. 2B-2C according to an example of the present disclosure.

FIG. 2E includes another perspective view of the latch assembly of FIG. 2D according to an example of the present disclosure.

FIG. 3 includes a perspective view of a pluggable module having the latch assembly of FIGS. 2D-2E according to an example of the present disclosure.

FIG. 4A includes a perspective view of the pluggable module of FIG. 3 latched to a wall of a cage according to an example of the present disclosure.

FIG. 4B includes a top view of a portion of the pluggable module latched to the wall of FIG. 4A according to an example of the present disclosure.

FIG. 5A includes a perspective view of an information processing device including a cage having a wall and the pluggable module latched to the wall of FIGS. 4A-4B according to an example of the present disclosure.

FIG. 5B includes a top view of a portion of the information processing device of FIG. 5A according to an example of the present disclosure.

FIG. 6A includes a perspective view of the pluggable module of FIGS. 4A-4B unlatched from the wall of the cage according to an example of the present disclosure.

FIG. 6B includes a top view of a portion of the pluggable module unlatched from the wall of FIG. 6A according to an example of the present disclosure.

FIG. 7 includes a top view of an information processing device including a cage having a wall, and the pluggable module unlatched from the wall of FIGS. 6A-6B according to an example of the present disclosure.

FIG. 8 is a flowchart depicting a method of uninstalling a pluggable module from an information processing device according to an example of the present disclosure.

### DETAILED DESCRIPTION

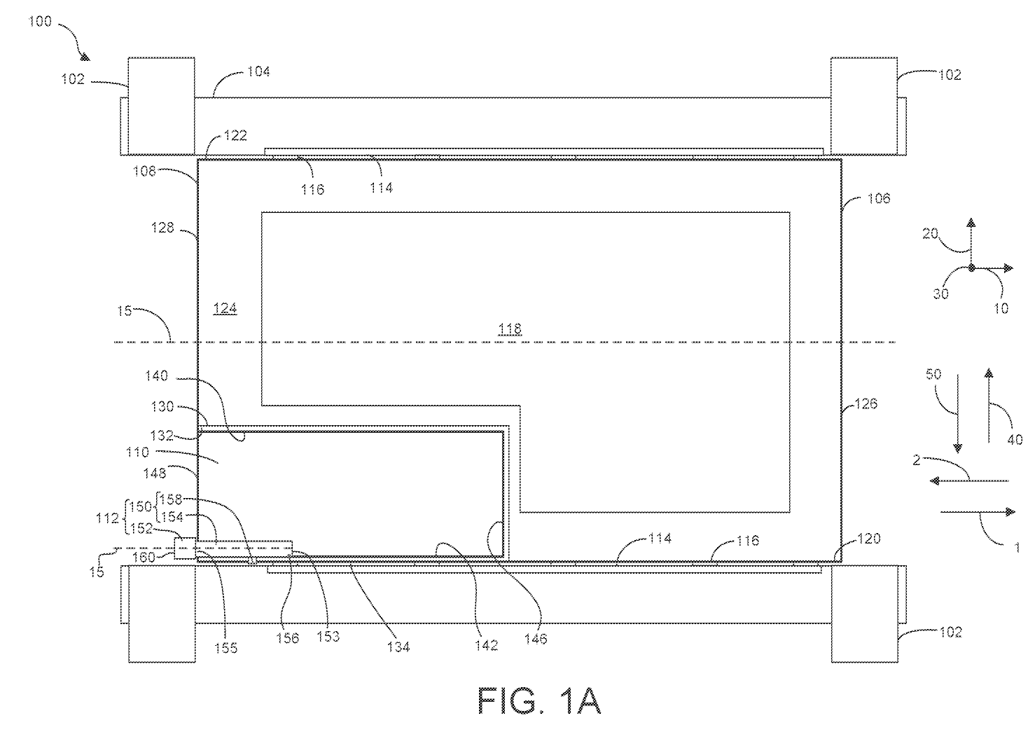

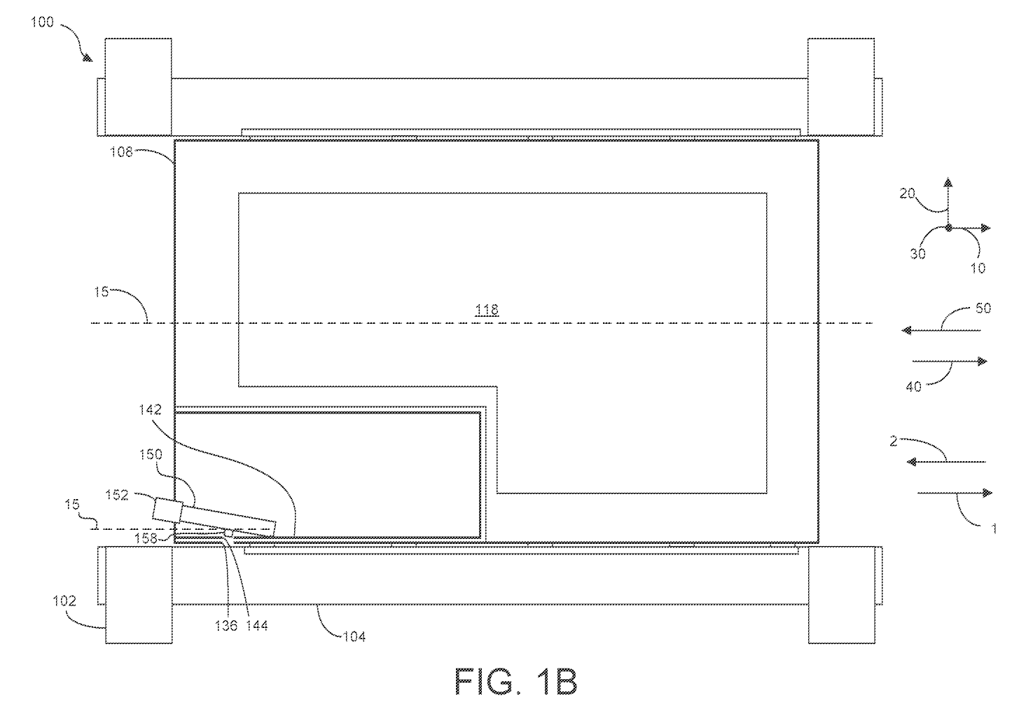

The following detailed description refers to the accompanying drawings. For purposes of explanation, certain examples are described with reference to the components illustrated in FIGS. 1-8. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the examples disclosed may be defined by the appended claims.

In many systems, pluggable modules can be conveniently installed in and uninstalled from an information processing device by sliding the pluggable module in and out of a chassis of the device. The chassis may have a bay configured to receive and the hold the pluggable module when installed. Further, the pluggable modules installed in the device may be securely fastened to the chassis by a latch assembly to ensure a stable and reliable connection between the module and the device. In some cases, the pluggable module may be equipped with a latching element that automatically engages with a complementary latching element of the chassis when the pluggable module is slid in place to ensure that the pluggable module is firmly secured to the chassis. The latching element may have a fixed end attached to a housing of the module and a free end which can be manually moved in a first lateral direction to actuate the latch between engaged and disengaged states, the first lateral direction being transverse to a longitudinal axis of the latching element. In such cases, to uninstall the pluggable module, the user may have to first disengage the latching element from the complementary latching element by manually moving the free end to actuate the latching element. With the latching element disengaged, the pluggable module may slide out of the chassis.

However, in some systems, when the pluggable module is installed in the device, the free end of the latching element may be positioned close to a portion of a support structure which supports the information processing device, such as a rail kit which attaches the device to a rack. This may leave a limited space (or a small clearance) between the latching element and the supporting structure for the user’s fingers to access the latching element. Additionally, the first lateral direction (the direction the free end is moved to disengage the latch) may point away from the supporting structure, and therefore to move the free end in the first lateral direction the user may need to insert their finger into the space between the latch element and the support structure to press laterally against a side face of the latching element. This can be difficult given the limited clearance between these two parts. In addition, to facilitate pressing laterally against the side of the latch element, the user may need to twist their hand to orient their finger such that its pad or tip can engage the side of the latch element. But orientating their finger in this manner can be difficult and/or non-ergonomic in some instances. Thus, it can be difficult to access and operate the existing latching element. This difficulty may be further heightened by obstructions from the supporting structure and/or other obstruction components of a system and may risk injury to user’s fingers.

A technical solution to the aforementioned problems involves providing a latch assembly with a handle that can be easily accessed and operated by the user's finger without requiring the user to press laterally against a side of the latch. In particular, the handle may be configured to allow the user to actuate the latch by pressing the handle longitudinally (i.e., parallel to a longitudinal axis of the latch). The handle may be configured to convert a longitudinal component of the force supplied by the user into lateral movement of the handle, thereby disengaging the latch. This approach may eliminate the need for the user's finger to press laterally against the side of the latch, which in turn eliminates the need for the user’s finger to fit into the limited clearance between the support structure and the handle and orient against the side of the latch. Specifically, the user's finger can be placed directly on a pressing surface of the handle that is oriented transversely to the longitudinal axis of the latch and apply a longitudinal force on such pressing surface to transition the latch assembly from a latched state to an unlatched state. In general, this orientation of the pressing surface allows for many possible poses of the pressing finger (and of the hand which includes the finger) including poses which are easier to attain and/or more ergonomic, given the constraints of the system, than the poses required to press against the side of the latch. This contrasts with existing latch assemblies, which require the user to insert their finger between the latch and the support structure and orient the finger to press against and apply a lateral force to the side of the latch to transition the latch assembly from the latched state to the unlatched state. Thus, the latches disclosed herein are easier and more ergonomic to actuate. In some examples, the pressing surface may be oriented perpendicular to the longitudinal axis and parallel to the rear panel of the pluggable module, thus facilitating ease of use.

Note that reference herein to the longitudinal axis refers to a longitudinal axis of the latch, which corresponds to a longest dimension of the latch, and which extends generally from the fixed end of the latch to the free end of the latch, unless indicated otherwise by the context. A longitudinal direction may be a direction which is parallel to the longitudinal axis. References herein to pressing the handle longitudinally, applying a longitudinal force to the handle, or similar references mean pressing in a direction or applying a force which points in a direction that includes a significant longitudinal component. Such references do not exclude the possibility that the pressing or force direction can also include other directional components, including a lateral component. In other words, the references herein to pressing or applying force longitudinally (or the like) do not mean that the pressing or force direction is exclusively longitudinal (unless explicitly indicated otherwise), but rather they can mean that the direction is at least partially longitudinal. Thus, for example, the pressing surface may allow for a finger to apply a force to the handle which is pointed at an acute angle relative to the longitudinal axis, such that part of the force urges the handle in the longitudinal direction (the longitudinal component) and part of the force urges the handle in the lateral direction (the lateral component), and this situation could appropriately be described herein as the finger pressing the handle longitudinally, applying a longitudinal force, or similar descriptions.

In one or more examples, the latch assembly includes a cantilever arm and a handle. The cantilever arm includes a beam portion that includes an attached end securely attached to a sidewall of the pluggable module and a free end opposite the attached end and movable relative to the sidewall. The cantilever arm also includes a catch that protrudes outwards from the beam portion. The catch is designed to interact with a corresponding catch opening located in a chassis of the information processing device. Specifically, the catch, in its latched state, may engage with the catch opening to firmly secure the pluggable module within the chassis. However, the catch, while transitioning from the latched state to the unlatched state, may disengage from the catch opening, allowing the pluggable module to be removed from the chassis.

The handle may be connected to the free end of the beam of the cantilever arm. The handle is designed with dual movement capabilities relative to the sidewall of the pluggable module. In the latched state, the handle can move in a first lateral direction which is transverse to the longitudinal axis of the cantilever arm. This movement causes the cantilever arm to transition from the latched state to the unlatched state. Conversely, when the cantilever arm is in the unlatched state, the handle can move in a second lateral direction, opposite to the first lateral direction, which transitions the cantilever arm back to the latched state. In some examples, the handle's design incorporates a mechanism that converts a longitudinal force, applied parallel to the longitudinal axis of the cantilever arm, into a lateral movement (in the first lateral direction). This conversion of force facilitates the transition of the cantilever arm from the latched state to the unlatched state, enabling efficient operation and user interaction with the latch assembly. To achieve this force conversion, the handle may include a feature, such as a ramp (or cam surface), that engages with the sidewall of the pluggable module. When a user applies a longitudinal force to the handle, the ramp translates this force into a lateral movement, effectively disengaging the catch from the catch opening. This mechanical advantage allows the user to unlatch the module with minimal effort.

In some examples, the handle may also feature a second pressing surface that is oriented perpendicular to the first pressing surface. This second surface is designed to receive a lateral force applied directly to it, enabling movement of the handle in the first lateral direction. This functionality can be utilized in situations where access to the second pressing surface is uninhibited, such as when the information processing device is not installed in the supporting structure, as one example. The inclusion of the second pressing surface provides an alternative way to actuate the latch to the disengaged state. The first pressing surface may be easier, more convenient, and/or more ergonomic to use in some situations, but in other situations some users might prefer to use the second pressing surface. Thus, including both options in the handle can allow the user to actuate the lever in whichever way they prefer given the particular situation.

In addition, the handle may be designed to incorporate additional features that enhance its usability and versatility. For example, the handle may include friction enhancing features (e.g., surfaces) formed on the first and/or second pressing surface (if present) to improve grip by increasing a roughness of the surface(s). The handle's design ensures that it is both functional and reliable, thereby providing a secure and user-friendly interface for the latch assembly.

In one or more examples, the handle's ability to convert longitudinal force into lateral movement simplifies the user interaction needed to latch and unlatch the pluggable module from the chassis, regardless of the handle's position relative to the rail kit. This ergonomic design makes the process more intuitive and reduces the effort required, thereby enhancing the overall user experience. Furthermore, the user can press against the pressing surface of the handle, which is oriented perpendicular to the longitudinal axis of the latch (parallel to a lateral direction). This orientation of the pressing surface of the handle makes accessing and operating the handle much easier and more intuitive. Additionally, this design helps prevent finger injuries that can result from scraping against rail kits and other obstructing components of a system.

In the description hereinafter, an example system and/or a rack and/or a support structure (e.g., rail kit) and/or an information processing device are described with the help of a reference frame shown in the several views which includes a horizontal axis 10, a lateral axis 20, and a vertical axis 30, which are marked in the Figures. Further, these axes 10, 20, and 30 may be perpendicular to each other, and the dimensions of components extending parallel to these axes 10, 20, and 30 may be referred to as a length, a width, and a height, respectively. Directions parallel to vertical axis 30 may be referred to herein as vertical and may include a first vertical direction (e.g., up) and a second vertical direction (e.g., down). Directions parallel to lateral axis 20 may be referred to herein as lateral and may include a first lateral direction 40 and second lateral direction 50. Directions parallel to horizontal axis 10 may include an insertion direction 1 and a retraction direction 2. The axes 10, 20, and 30 and directions or positional relationships described herein in relation to these axes are fixed relative to the information processing device as shown in the figures and not to any external reference frame (such as the ground), and direction terms used herein should be understood in relation to these axes and not to any external reference frame. For example, horizontal and vertical, as used herein, do not refer to orientations relative to the ground. In addition, various directions and positional relationships may be described herein with reference to a longitudinal axis 15 of a latch assembly 112 (described below). This longitudinal axis 15 is fixed relative to the latch assembly 112 and is parallel to a longitudinal (i.e., longest) dimension of the latch assembly 112 when the latch assembly 112 is in its resting state. The longitudinal axis 15 may extend parallel to the horizontal axis 10 when the pluggable module 110 is installed in the information processing device 106, in some examples.

Referring to the Figures, FIG. 1A depicts a schematic top view of a system 100 including a rack 102, a support structure (e.g., rail kit 104), and an information processing device 106 mounted to the rail kit 104, where the information processing device 106 includes a chassis 108 and a pluggable module 110 with a latch assembly 112 in a latched state to secure the pluggable module 110 to the information processing device 106. FIG. 1B depicts a schematic top view of the system 100 of FIG. 1A having the latch assembly 112 in an unlatched state to release the pluggable module 110 from the information processing device 106. It should be understood that FIGS. 1A-1B are not intended to illustrate specific shapes, dimensions, or other structural details accurately or to scale, and that implementations of the system 100 and the system 100 may have different numbers and arrangements of the illustrated components and may also include other parts that are not illustrated. The system 100 may be configured to host multiple information processing devices 106 and associated components therein. In the description hereinafter, FIGS. 1A-1B are described concurrently.

The rack 102 includes a standardized post configured to allow mounting of multiple information processing devices 106 via a mounting system (such as a rail kit 104). In some examples, the rack 102 has a four-post rack with posts positioned at each of the four corners, creating an enclosure framework. In other examples, the rack 102 may have another rack configuration, such as a two-post rack configuration or any other rack configuration. In some examples, the enclosure framework may be designed to accommodate multiple information processing devices 106 via the rail kits 104. In one or more examples, the rail kits 104 and the information processing devices 106 are vertically stacked along a vertical axis 30. In particular, the posts may include mounting features (e.g., apertures) distributed along the vertical axis 30 at predetermined positions, with these mounting features being arranged to engage with corresponding mounting features of the rail kits/devices to secure them to the posts of the rack 102. It may be noted herein that the examples of FIGS. 1A-1B show only one rail kit 104 and information processing device 106, for ease of illustration.

The rail kit 104 is a framework configured to mount the information processing device 106 to the rack 102. The rail kit 104 includes two mounting rails, each having a track 114 located on one side (not labeled) of a corresponding mounting rail and extending along the horizontal axis 10 in a coupled state of the information processing device 106 to the rail kit 104. In a state in which the pluggable module 110 is installed in the information processing device 106 and the device 106 is mounted to the rail kit 104, the rail kit 104 may also extend parallel to the longitudinal axis 15. The tracks 114 may allow a plurality of spools 116 of the information processing device 106 to slide therein to mount the information processing device 106 to the rack 102. While rail kit may advantageously allow for information processing devices to be slid out of the rack without detaching the devices from the rack (e.g., for maintenance), it is possible for one or more (in some cases, all) of the information processing devices, which can include the information processing device 106, to be mounted directly to the rack 102 without using any rail kits.

The rack 102 and rail kit 104 are illustrated as examples of supporting structures to which device 106 may be mounted, but it should be understood that the device 106 could be mounted to any of a variety of supporting structures, such as a system chassis of a multi-node system (e.g., a blade system or HPC system), a rack without rail kits, or others. In addition, the device 106 does not necessarily have to be mounted to any support structure at all and may instead rest on a desk or other surface, for example.

The information processing device 106, such as a server, includes a chassis 108, a pluggable module 110, and a plurality of spools 116. As used herein, an "information processing device" may be a rack-mount server, tower server, blade server, storage array, storage enclosure, computer cluster, high performance compute (HPC) system, node or tray of a multi-unit system (such as an HPC system), system/chassis controller of a multi-unit system, a networking device (e.g., switch, router, etc.), or any other device or equipment including a controller, a processing resource, or the like. The chassis 108 may be an enclosure configured to house and provide support to electronic components of the information processing device 106. In some examples, the chassis 108 may be formed by a first peripheral side 120, a second peripheral side 122, a base 124, a cover (not shown), a rear panel 126, and a front panel 128. Each of the first peripheral side 120 and the second peripheral side 122 extends parallel to one another along the horizontal axis 10 of the chassis 108. Further, the first and second peripheral sides 120, 122, respectively, may be connected to the base 124, the cover, the rear and front panels 126, 128, respectively, to define an internal volume (not labeled) of the chassis 108 which may be configured to house and provide support to the electronic components such as a primary system board 118, or the like. In some examples, the chassis 108 further includes a cage 130 disposed adjacent to the first peripheral side 120 and the front panel 128, for example. In some non-limiting examples, the cage 130 may be disposed in any other convenient location of the chassis 108 e.g., adjacent to the second peripheral side 122 and the rear panel 126, or the like. The cage 130 may define a bay 132 configured to receive the pluggable module 110. The cage 130 may include a wall 134 disposed adjacent to the first peripheral side 120 of the chassis 108. The wall 134 includes a catch opening 136 (as labeled in FIG. 1B) configured to engage with a catch 158 of the latch assembly 112 to secure the pluggable module 110 to the information processing device 106.

The plurality of spools 116 is disposed spaced apart from one another and extends perpendicularly from each of the first and second peripheral sides 120, 122 in a mutually opposite direction along a lateral axis 20 of the chassis 108. In some examples, the plurality of spools 116 may be configured to directly mount the information processing device 106 to a four-post rack 102 through the rail kit 104. For example, each spool 116 may be configured to engage with and travel along the track 114 of the corresponding mounting rail of the rail kit 104 to mount the information processing device 106 to the rack 102.

The pluggable module 110 may be a module of the information processing device 106 configured to be removably plugged into the bay 132. In some examples, the pluggable module 110 is configured to be installable in or removable from the bay 132 from outside the chassis 108 without requiring disassembly of the device 106 (e.g., without requiring opening of the chassis 108). In some examples, the pluggable module 110 is hot-swappable. In some examples, the pluggable module 110 may be added to or removed from the information processing device 106 while the information processing device 106 is installed in the rack 102, to increase or decrease performance of the information processing device 106. In some examples, the pluggable module 110, such as a hard drive, power supply unit, transceiver, network interface card, and the like, includes a housing 140 configured to house electronic components (not shown) of the pluggable module 110 and a latch assembly 112 to secure and/or release the pluggable module from the information processing device 106. The housing 140 includes a front panel 146, a rear panel 148 opposite the front panel 146, and a sidewall 142 having an aperture 144 therein. In some examples, the latch assembly 112 is coupled to the pluggable module 110 and is configured to detachably engage with the chassis 108 to secure and release the pluggable module 110 from the chassis 108. In one or more examples, the latch assembly 112 includes a cantilever arm 150 and a handle 152.

The cantilever arm 150 includes a beam portion 154 and a catch 158. In some examples, the beam portion 154 has a fixed end portion 153 attached to the sidewall 142 and a free end portion 155 opposite the fixed end portion 153, with the beam portion 154 extending along a longitudinal axis 15 of the latch assembly 112 between these end portions 153/155. The fixed end portion 153 may be attached to the sidewall 142 via a fastener 156, welding, or any other desired fastening technique. In one or more examples, the fixed end portion 153 is immovably attached to the side wall 142 and the beam portion 154 is a spring arm configured to bend in response to lateral movement of the free end portion 155 and to generate a restoring spring force in response to such bending, urging the beam portion 154 back to a resting or nominal position. In other examples, the fixed end portion 153 may be pivotably connected to the side wall 142 such that the beam portion 154 does not necessarily bend in response to lateral movement of the free end portion 155, in which case a separate spring (not illustrated) may be provided to urge the beam portion 154 towards the resting or nominal position. In some examples, the resting or nominal position of the beam portion 154 is configured to be one in which the longitudinal axis 15 is parallel to the sidewall 142 and the horizontal axis 10. In other words, the spring forces may bias the beam portion 154 to remain parallel to the sidewall 142. As will be explained in greater detail below, this position of the beam portion 154 also corresponds to a latched state of the cantilever arm 150, and therefore the spring forces may bias the cantilever arm 150 into the latched state. Further, the free end portion 155 of the beam portion 154 is movably connected to the handle 152. In some examples, the free end portion 155 of the beam portion 154 is movable along the lateral axis 20 relative to the sidewall 142 between the latched state and the unlatched state.

The catch 158 is a rigid member protruding from one side of the cantilever arm 150. The catch 158 protrudes from the side of the cantilever arm 150 that is disposed adjacent to the sidewall 142. In some examples, in the latched state of the cantilever arm 150 shown in FIG. 1A, the catch 158 extends through the aperture 144 and is configured to engage with a catch opening 136 in the chassis 108 to secure the pluggable module 110 to the chassis 108. In the unlatched state of the cantilever arm 150 shown in FIG. 1B, the catch 158 is configured to disengage from the catch opening 136 to release the pluggable module 110 from the chassis 108.

The handle 152 is movably (e.g., slidably) connected to the cantilever arm 150. For example, the free end portion 155 of the beam portion 154 is movably connected to the handle 152. Further, the handle 152 includes a pressing surface 160 (or a first pressing surface) oriented transverse to the longitudinal axis 15. As used herein, “transverse” refers to a positional relationship of two items in which one item is oriented crosswise at an angle relative to the other item, such as being substantially or generally perpendicular to the other item. As used herein, “transverse” includes, but does not require, an exactly perpendicular relationship. In some examples, the pressing surface 160 is oriented perpendicular to the longitudinal axis 15 and parallel to a rear panel 148 of the pluggable module 110. In such examples, the pressing surface 160 may be accessible and operable by the user’s finger positioned along the longitudinal axis 15 so as to move the cantilever arm 150 from its latched state to the unlatched state.

In one or more examples, the pluggable module 110 may be disposed in the information processing device 106. In particular, the pluggable module 110 may be installed in the bay 132 defined by the cage 130 of the chassis 108 by slidably inserting the pluggable module 110 along an insertion direction 1, which is parallel to the longitudinal axis 15. More particularly, the pluggable module 110 is inserted into the bay 132 via the front panel 128 of the chassis 108 until the rear panel 148 of the pluggable module 110 is aligned with the front panel 128 of the chassis 108. During insertion, the cantilever arm 150 is moved to the unlatched state to allow the catch 158 to move past the leading edge of the wall 134. In some examples, this movement of the cantilever arm 150 to the unlatched state may be achieved by manually applying a force to the handle 152 to move the handle 152 in the first lateral direction 40. In other examples, the catch 158 may be configured to automatically transition the cantilever arm 150 to the unlatched state as the pluggable module 110 is slidably inserted into the bay 132. For example, the catch 158 may include sloped surfaces configured to engage with and ride up a leading edge of the wall 134, converting motion of the catch 158 along the insertion direction 1 into motion in the first lateral direction 40 until the catch 158 has moved sufficiently to clear the leading edge of the wall 134. This motion of the catch 158 in the first lateral direction 40 is facilitated by the beam 154 bending or pivoting, which in turn results in the free end portion 155 and handle 160 moving in the first lateral direction 40 (although without being directly manipulated by the user, in this case). Once the module 110 reaches a fully installed position, the catch 158 becomes aligned with the catch opening 136, which allows catch 158 to move into and engage with the catch opening 136, which returns the beam 154 back to its resting or nominal position. The return of the beam 154 to its resting or nominal position may be driven by the restoring spring forces of the beam 154 (or a separate spring), by the user manually moving the handle 152 in a second lateral direction 50 opposite the first lateral direction 40, or a combination of the two. Thus, securing the pluggable module 110 to the information processing device 106.

In the latched state of the cantilever arm 150, the latch assembly 112 is positioned adjacent to the rail kit 104 and/or the post of the rack 102, if the information processing devices 106 is installed in one. However, the pressing surface 160 of the handle 152 is parallel to the lateral axis 20, making it easily accessible and operable by a user's finger positioned along the longitudinal axis 15. Hence, the handle 152 can be easily operated by mere application of a longitudinal force directly on the pressing surface 160 of the handle 152. In such examples, when the longitudinal force is applied on the pressing surface 160 of the handle 152 by the user’s finger, the handle 152 moves relative to the cantilever arm 150 and parallel to the longitudinal axis 15 (e.g., along insertion direction 1). For instance, the handle 152 may slide from a first position to a second position down the cantilever arm 150. The handle 152 may further convert this movement of the handle 152 relative to the cantilever arm 150 into movement of the handle 152 relative to the sidewall 142 in the first lateral direction 40. More specifically, the motion of the handle 152 relative to the sidewall 142 includes both a motion component along with the first lateral direction 40 and a motion component along the insertion direction 1. Thus, longitudinal force applied on the pressing surface 160 of the handle 152 causes the handle 152 to move relative to the side wall 142 in the first lateral direction 40 transverse to the longitudinal axis 15 (as well as also moving in the insertion direction 1).

In some examples, the handle 152 may include a ramp (not shown in FIGS. 1A-1B) arranged to contact an edge of the sidewall 142 of the pluggable module 110 to convert the longitudinal force into the movement along the first lateral direction 40. For example, the movement of the handle 152 relative to the cantilever arm 150 parallel to the longitudinal axis 15 is converted into movement of the handle 152 relative to the sidewall 142 in the first lateral direction 40 by the ramp sliding along the edge of the sidewall 142. It may be noted that the steps involved in converting the movement of the handle 152 relative to the cantilever arm 150 parallel to the longitudinal axis 15 into the movement of the handle 152 relative to the sidewall 142 in the first lateral direction 40 are explained in detail below. In one or more examples, when the handle 152 converts the longitudinal force applied on it into the movement of the handle 152 in the first lateral direction 40, the handle 152 may further move the free end portion 155 of the cantilever arm 150 along the first lateral direction 40, transitioning the cantilever arm 150 from the latched state to the unlatched state. Accordingly, the cantilever arm 150 may move the catch 158 along the lateral axis 20 to disengage from the catch opening 136 and release the pluggable module 110 from the chassis 108.

The pluggable module 110, in the unlatched state of the cantilever arm 150, may be pulled out of the information processing device 106. In particular, the pluggable module 110 may be uninstalled from the bay 132 by slidably extracting the pluggable module 110 along an extraction direction 2 opposite to the insertion direction 1 and which is parallel to the longitudinal axis 15. More particularly, the pluggable module 110 is extracted from the bay 132 via the front panel 128 of the chassis 108.

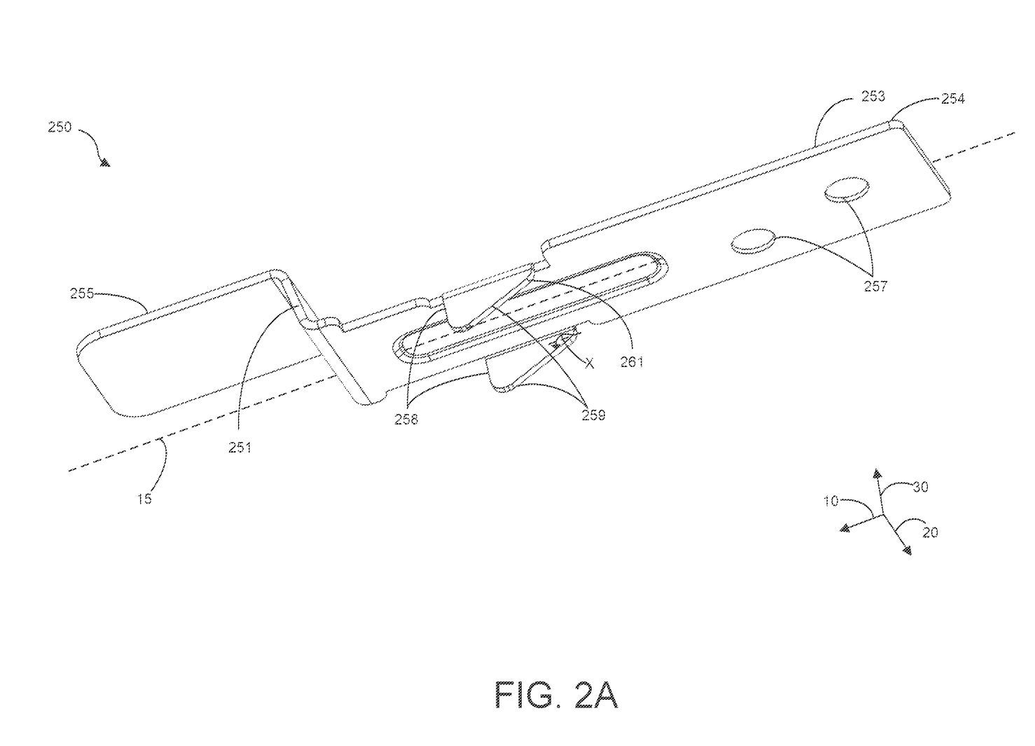

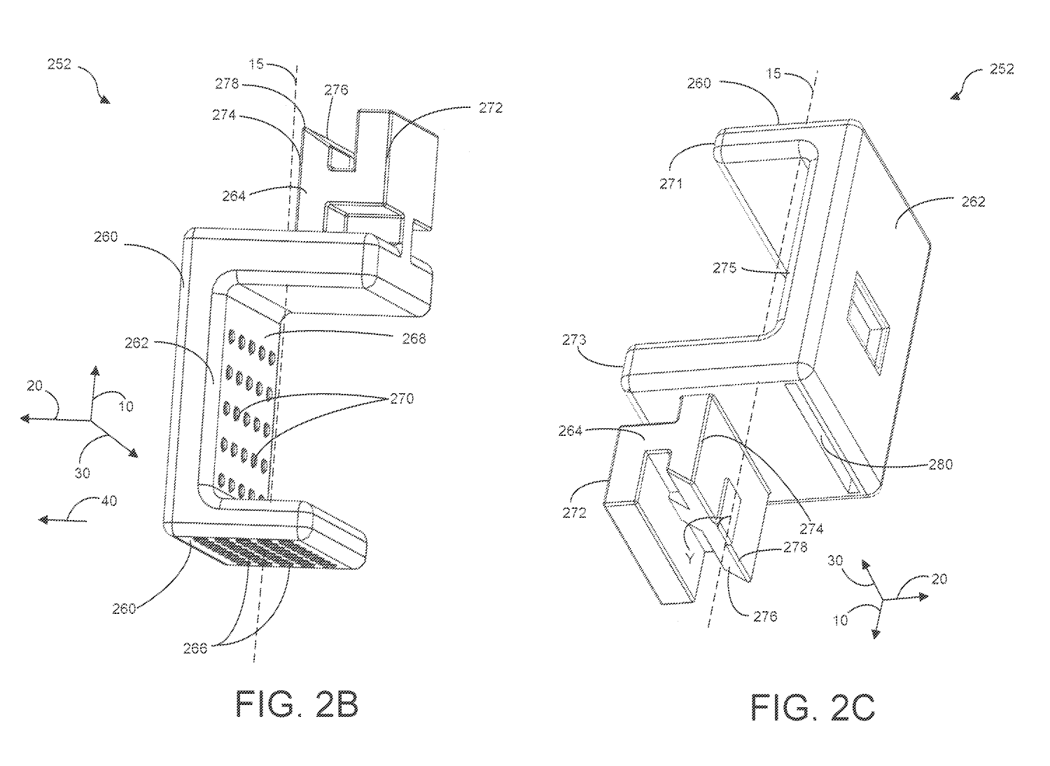

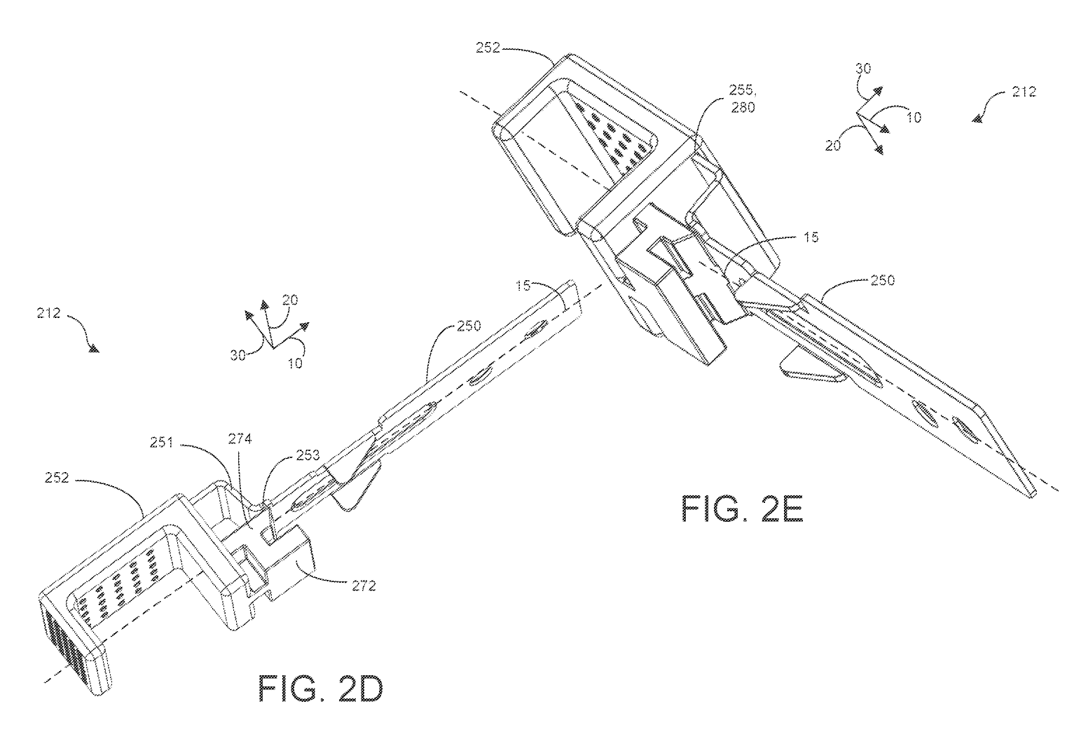

Turning now to FIGS. 2A-E, a latch assembly 212 and a pluggable module 310 in which the latch assembly 212 may be included are described. The latch assembly 212 is one example implementation of the latch assembly 112 described above, and the pluggable module 310 is one example implementation of the pluggable module 110 described above. Components of the latch assembly 212 and the pluggable module 310 which correspond to (e.g., are examples of) components of the latch assembly 112 and the pluggable module 110, respectively, are given similar reference numbers herein which have the same last two digits, such as 160 and 260. The latch assembly 112 and the pluggable module 110 are not limited to the latch assembly 212 and pluggable module 310, and the description below of the components of latch assembly 212 and pluggable module 310 do not limit the corresponding components of the latch assembly 112 and the pluggable module 110. Furthermore, pluggable module 310 is just one example of a type of pluggable module that the latch assembly 212 can be used with, and the latch assembly 212 is not limited to just the pluggable module 310.

FIG. 2A depicts a perspective view of a cantilever arm 250 of a latch assembly 212 in isolation. FIGS. 2B and 2C depict a handle 260 of the latch assembly 212 in isolation. FIGS. 2D and 2E illustrate the fully assembled latch assembly 212 with handle 260 coupled to cantilever arm 250. In FIGS. 2A-2E, a reference frame with coordinate axes 10, 20, and 30 is provided, with these coordinate axes being defined as described above in relation to FIG. 2.

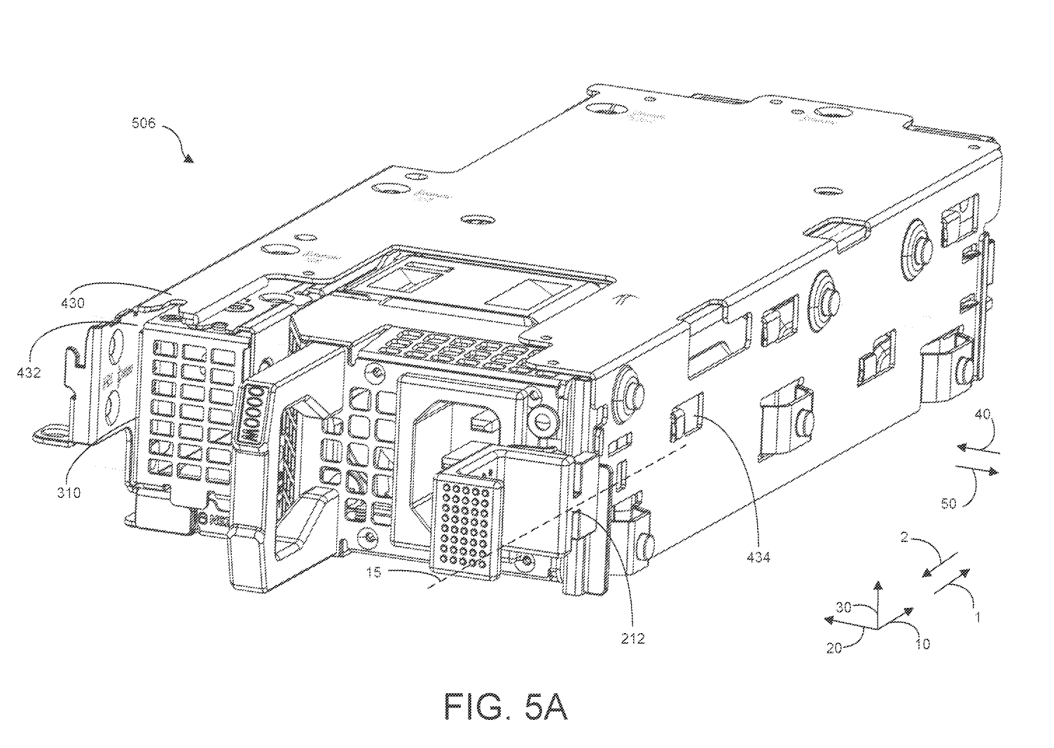

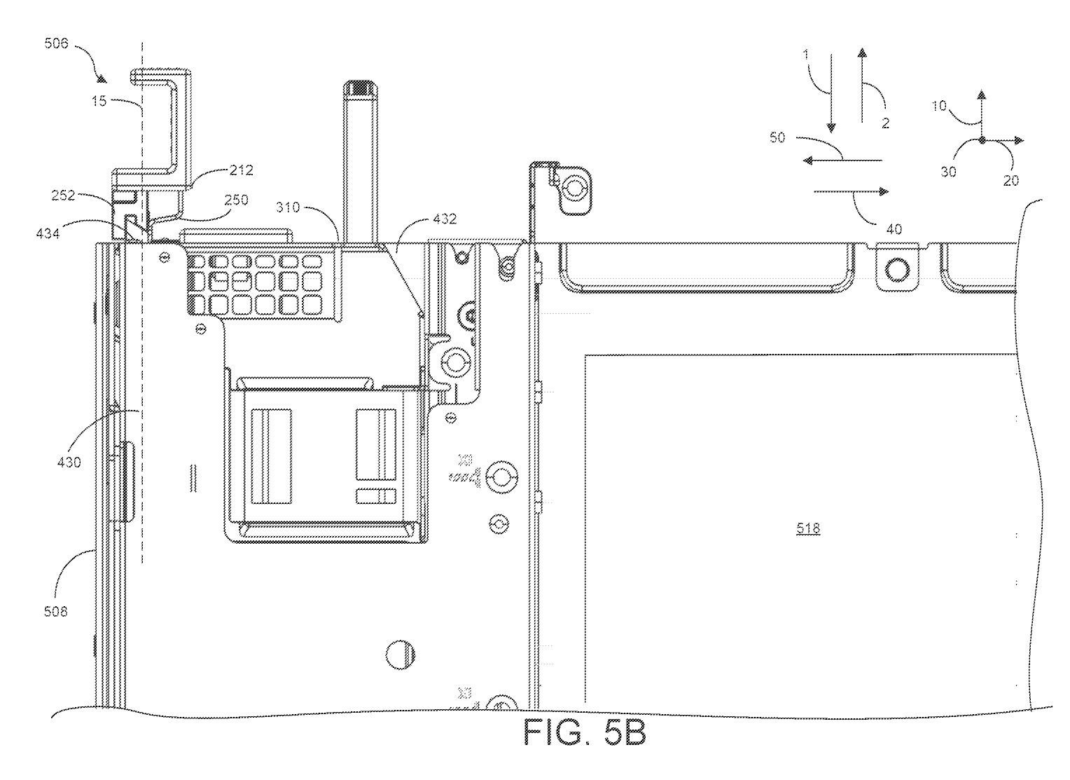

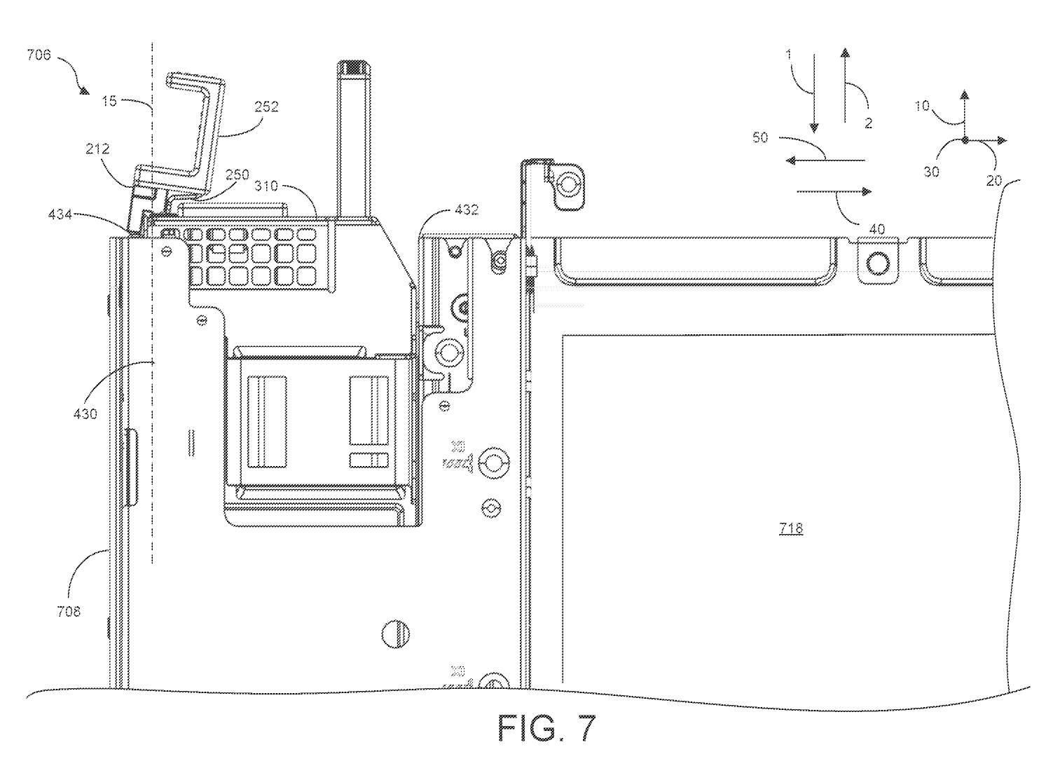

The cantilever arm 250 includes a beam portion 254 and a pair of catches 258. The cantilever arm 250 is configured to move along a lateral axis 20 to secure the pluggable module to a chassis 508 of an information processing device 506 (as shown in FIGS. 5A-5B) and release the pluggable module from a chassis 708 of an information processing device 706 (as shown in FIG. 7).

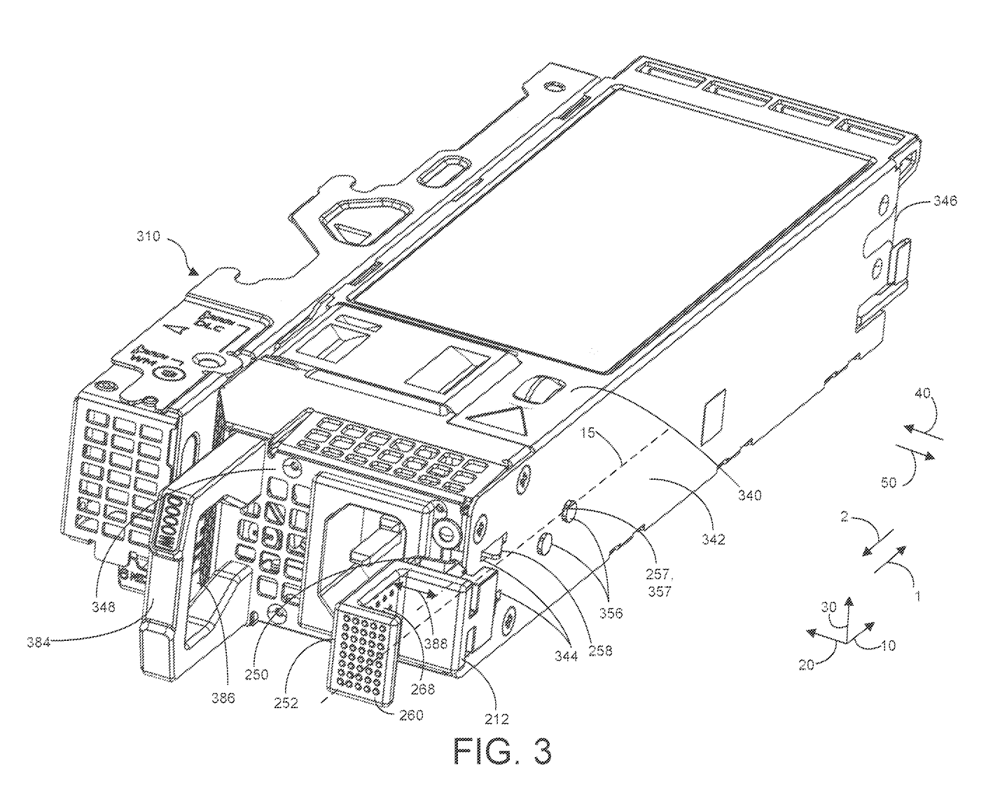

The beam portion 254 is made of a compliant material capable of elastic deformation within the operational range of motion of the beam portion 254, such as various metals and plastics. For example, the beam portion 254 may be a spring arm made from spring steel. The beam portion 254 may include a fixed end portion 253 and a free end portion 255 opposite the fixed end portion 253, with each extending along a longitudinal axis 15 of the latch assembly 212. This longitudinal axis 15 is aligned with horizontal axis 10 when the beam portion 254 is in its resting/nominal position. The beam portion 254 may further include a body portion 251 extending along a vertical axis 30 and connecting the fixed end portion 253 to the free end portion 255 such that the beam portion 254 is stepped. In some examples, the fixed end portion 253 and the free end portion 255 are offset from each other along the lateral axis 20 by a distance substantially equal to a length of the body portion 251. In one or more examples, the fixed end portion 253 includes a pair of mounting holes 257, which may be used to attach the beam portion 254 to a sidewall 342 of a pluggable module 310 (as shown in FIG. 3). Further, the free end portion 255 of the beam portion 254 may be connected to a handle 252 of the latch assembly 212. In some examples, the beam portion 254 is configured to be movable relative to the sidewall 342 in a first lateral direction 40 or a second lateral direction 50 transverse to the pluggable module 310 or bendable relative to mounting points of the beam portion 254 with the sidewall 342 of the pluggable module 310.

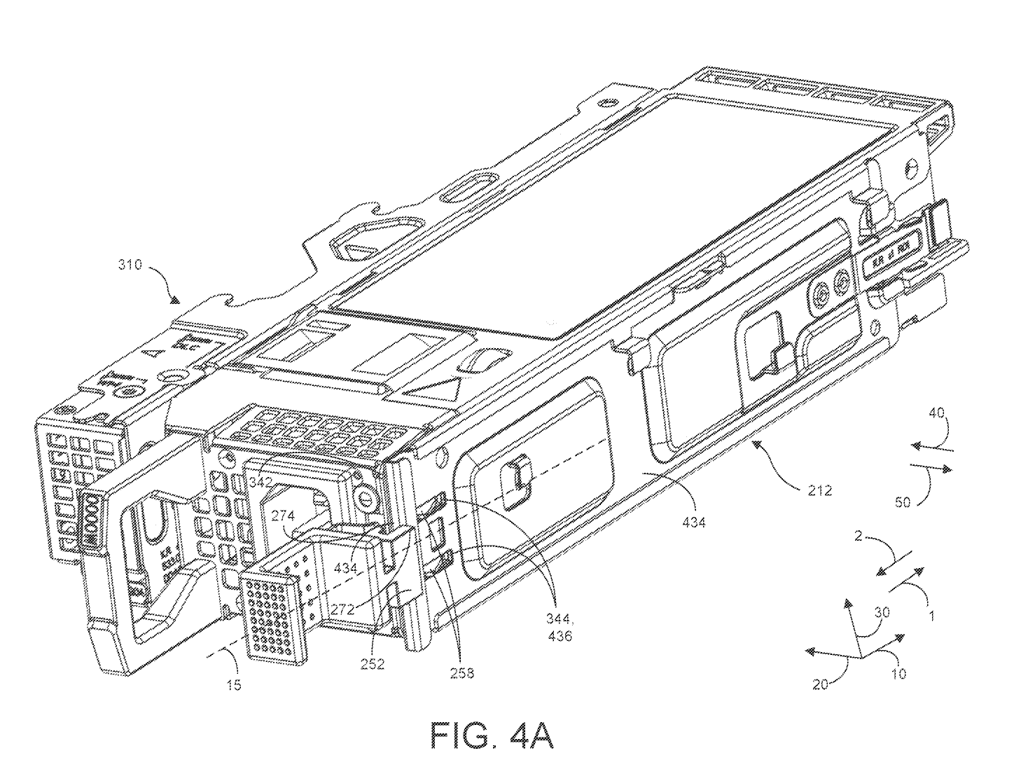

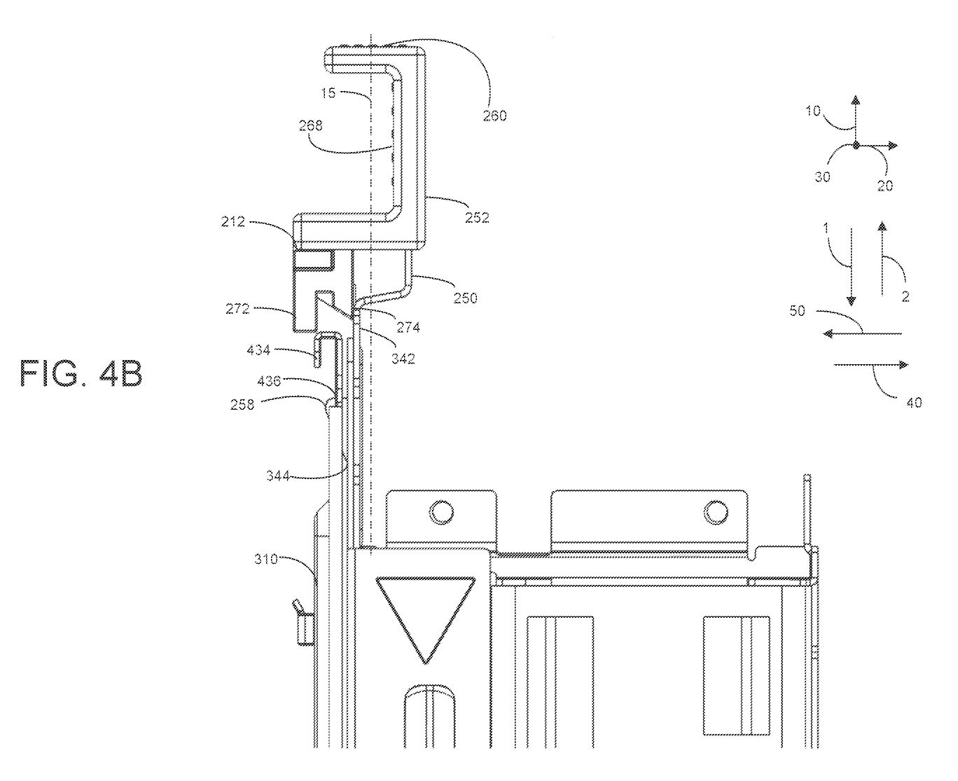

The pair of catches 258 is a made of rigid material. In some examples, the pair of catches 258 is disposed parallelly spaced apart from one another along the lateral axis 20. Further, each catch 258 protrudes outwards from a lower side of the cantilever arm 250 along the vertical axis 30. In other words, each catch 258 is an overhanging member from the beam portion 254. Further, each catch 258 has a wedge portion 259 at its distal end 261. In certain examples, the wedge portion 259 may be inclined at an angle α relative to the longitudinal axis 15. In some examples, the angle α may be 20 degrees. In some examples, in the latched state of the cantilever arm 250, each catch 258 may extend through a corresponding aperture (as shown in FIG. 3) of a pair of apertures 344 in the sidewall 342 of the pluggable module 310 and engage with a corresponding catch opening 436 (as shown in FIGS. 4A-4B) in a cage 430 installed in a chassis 508 to secure the pluggable module 310 to the chassis 508 of an information processing device 506 (as shown in FIGS. 5A-5B). Similarly, in the unlatched state of the cantilever arm 250, each catch 258 may be configured to disengage from a corresponding catch opening 736 in a cage 730 installed in a chassis 708 to release the pluggable module 310 from the chassis 708 of an information processing device 706 (as shown in FIG. 7).

FIG. 2B depicts a perspective view of a handle 252 of a latch assembly 212. FIG. 2C depicts another perspective view of the handle 252 of FIG. 2B. In the description hereinafter, FIGS. 2B-2C are described concurrently. The handle 252 may be connected to the cantilever arm 250 (as shown in FIG. 2A) and configured to drive the cantilever arm 250 between a latched and unlatched state. In some examples, the handle 252 includes a driver section 262 and an engagement section 264 extending from the driver section 262.

The driver section 262 is a U-shaped element having an upper leg 271, a lower leg 273, and an intermediary leg 275 connecting the upper leg 271 with the lower leg 273. In some examples, the handle 252 includes a first pressing surface 260 formed on the upper leg 271 of the U-shaped element. Further, the first pressing surface 260 is oriented transverse to a longitudinal axis 15. In some other examples, the first pressing surface 260 is oriented perpendicular to the longitudinal axis 15. Further, in the installed state of the cantilever arm 250 of the latch assembly 210, in a pluggable module 310 (as shown in FIG. 3), the first pressing surface 260 is configured to be oriented parallel to a rear panel 248 of the pluggable module 310. Therefore, the first pressing surface 260 is easily accessible to receive a longitudinal force applied by a user finger positioned along the longitudinal axis 15. In some examples, the first pressing surface 260 includes friction enhancing features 266, such as corrugated bumps, configured to increase a roughness of the first pressing surface 260, thereby increasing a friction between the user’s finger and the first pressing surface 260.

The handle 252 further includes a second pressing surface 268 recessed relative to the sidewall 342 of the pluggable module 310 by a distance along the first lateral direction 40 of at least 1 cm to facilitate the user access to the second pressing surface 268. In other words, the second pressing surface 268 is formed on the intermediary leg 275 of the U-shaped element. In such examples, the second pressing surface 268 is oriented along the longitudinal axis 15. In one or more examples, the second pressing surface 268 is further accessible to receive a lateral force applied by the user finger positioned along a lateral axis 20. In some examples, the second pressing surface 268 includes second friction enhancing features 270, such as corrugated bumps, configured to increase a roughness of the second pressing surface 268, thereby increasing a friction between the user’s finger and the second pressing surface 268.

The driver section 262 further includes a hole 280 extending perpendicularly inwards from one side of the driver section 262 along the longitudinal axis 15. In other words, the hole 280 is formed in the lower leg 273 of the U-shaped element and extends into the intermediary leg 275 of the U-shaped element. The hole 280 may be configured to engage with a free end portion 255 of the cantilever arm 250 (as shown in FIG. 2A) to movably (e.g., slidably) couple the handle 252 to the cantilever arm 250.

The engagement section 264 extends perpendicularly outwards from another side of the driver section 262 along the longitudinal axis 15. The engagement section 264 includes a first wall 272 and a second wall 274 which are disposed parallelly spaced apart from one another. In some examples, in the installed state of the pluggable module 310 in an information processing device 506 (as shown in FIGS. 5A-5B), the first wall 272 is configured to contact a wall 434 of a cage 430 installed in a chassis 508 of the information processing device 506. The second wall 274 has a ramp 276 at its distal end 278. In certain examples, the ramp 276 may be inclined at an angle β relative to the longitudinal axis 15. In some examples, the angle β may be 50 degrees. In such examples, in the installed state of the pluggable module 310 in an information processing device 506 (as shown in FIGS. 5A-5B), the ramp 276 of the second wall 274 is configured to contact the sidewall 342 of the pluggable module 310.

FIG. 2D depicts a perspective view of a latch assembly 212 including the cantilever arm 250 of FIG. 2A and the handle 252 of FIGS. 2B-2C. FIG. 2E depicts another perspective view of the latch assembly 212 of FIG. 2D. In the description hereinafter, FIGS. 2D-2E are described concurrently. The latch assembly 212 may be attached to a pluggable module 310 (as shown in FIG. 3), operated to secure the pluggable module 310 to a chassis 508 of an information processing device 506 (as shown in FIGS. 5A-5B), and operated to release the pluggable module 310 from a chassis 708 of an information processing device 706 (as shown in FIG. 7). In some examples, the handle 252 is movably connected to the cantilever arm 250 to form the latch assembly 212. In particular, the free end portion 255 of the beam portion 254 is engaged with the hole 280 of the handle 252 to movably connect the cantilever arm 250 to the handle 252. In such examples, the second wall 274 of the handle 252 is positioned adjacent to the body portion 251 and the fixed end portion 253 of the cantilever arm 250 and the sidewall 342 of the pluggable module. Further, the first wall 272 is configured to be positioned adjacent to the wall 434 of the cage 430.

FIG. 3 depicts a perspective view of a pluggable module 310 having the latch assembly 212 of FIGS. 2D-2E. The pluggable module 310 may be a hard drive, power supply unit, transceiver, network interface card, or the like. In the example of FIG. 3, the pluggable module 310 is a power supply unit. The pluggable module 310 has a housing 340 to provide support for electronic components (not labeled) and the latch assembly 212 disposed therein. The housing 340 includes a front panel 346, a rear panel 348 opposite the front panel 346, and a sidewall 342 having a pair of apertures 344 and a pair of second mounting holes 357. The pair of apertures 344 are disposed parallelly spaced apart from one another along the vertical axis 30. The pair of second mounting holes 357 are disposed spaced apart from one another along the longitudinal axis 15. In some examples, the latch assembly 212 is disposed within the housing 340 and positioned adjacent to the sidewall 342 such the pair of mounting holes 257 of the cantilever arm 250 is aligned with the pair of second mounting holes 357 of the sidewall 342, and the pair of catches 258 of the cantilever arm 250 extends through the pair of apertures 344 in the sidewall 342. In such examples, the beam portion 254 of the cantilever arm 250 is coupled to the sidewall 342 of the pluggable module 310 through a pair of fasteners 356 that extends through the pair of mounting holes 257 in the cantilever arm 250 and the pair of second mounting holes 357 in the sidewall 342.

In the example of FIG. 3, the latch assembly 210 is in the latched state. As discussed herein, a handle 252 of the latch assembly 212 includes a first pressing surface 260 oriented transverse to the longitudinal axis 15 and a second pressing surface 268 oriented transverse to the first pressing surface 260 or along the longitudinal axis 15. In some other examples, the first pressing surface 260 of the handle 252 is oriented perpendicular to the longitudinal axis 15 and parallel to a rear panel 348 of the pluggable module 310. The first pressing surface 260 is configured to receive a longitudinal force applied directly on the first pressing surface 260 along an insertion direction 1 parallel to the longitudinal axis 15. The second pressing surface 268 is recessed relative to the sidewall 342 by a distance 388 along the first lateral direction 40 of at least 1 cm to facilitate the user access to the second pressing surface 268. Further, the second pressing surface 268 is configured to receive a lateral force applied directly on the second pressing surface 268 along the first lateral direction 40 to move the handle along the first lateral direction 40.

The pluggable module 310 further includes a second handle 384 attached to the housing 340 and includes a recess 386 to allow the user’s other fingers to extend therethrough to clasp the second handle 384. The user may clasp the second handle 384 and either push or pull the pluggable module 310 along the insertion direction 1 or the extraction direction 2 to install or uninstall the pluggable module 310 in the device. In some examples, the user may use the second handle 384 and the latch assembly 212 to uninstall or install the pluggable module 310 using a single hand. For instance, while clasping the second handle 384 with a first set of finger(s) on a hand (e.g., index finger and/or middle finger), the user may, using a second set of finger(s) on the hand (e.g., a thumb), apply a longitudinal force on the handle 252 to move the latch assembly 212 between the latched and unlatched states.

In this regard, the user may uninstall the pluggable module 310 by pressing the first pressing surface 260 with the second set of finger(s) to unlatch the latch assembly 212 and, while holding the latch assembly 212 in the unlatched state using the second set of fingers, pulling the pluggable module 310 out of the bay via the second handle 384 using the first set of finger(s). The user may install the pluggable module 310 by pushing the pluggable module 310 via the second handle 384 using the first set of finger(s). As described herein, in some cases, the user may further install the pluggable module 310 by, while pushing the second handle 384, pressing the first pressing surface 260 using the second set of finger(s) to move the latch assembly 212 to the unlatched state and subsequently releasing the first pressing surface to move the latch assembly 212 to the latched state. Further, in some examples, the user may install or uninstall the pluggable module 310 by pressing the second pressing surface 268 with the second set of finger(s) while clasping the second handle 384 using the first set of finger(s).

In comparison with latch designs that involve fitting and/or orienting a finger into a limited space, examples described herein may facilitate installing or uninstalling the pluggable module 310 with a single hand with greater ease and comfort (e.g., improved ergonomics). In this regard, because the first pressing surface 260 is oriented transverse to the longitudinal axis 15, the user may comfortably clasp the second handle 384 with some fingers while pressing the first pressing surface 260 with another finger without twisting that finger. Further, because the second pressing surface 268 is recessed, the user may more readily position a finger on the second pressing surface 268 than with designs having more limited clearance. Accordingly, the user may comfortably clasp the second handle 384 while pressing the second pressing surface 268.

In some examples, a user may use multiple hands to install or uninstall the pluggable module 310. For instance, one hand may be used to apply the longitudinal force on the handle 252 to move the latch assembly 212 to the unlatched state, and simultaneously another hand may be used to clasp the second handle 384 and either push or pull the pluggable module 310 along the insertion direction 1 or the extraction direction 2 to uninstall or install the pluggable module 310 in the device.

FIG. 4A depicts a perspective view of the pluggable module 310 of FIG. 3 latched to a wall 434 of a cage 430. FIG. 4B depicts a top view of a portion of the pluggable module 310 latched to the wall 434 of FIG. 4A. In the description hereinafter, FIGS. 4A-4B are described concurrently.

The wall 434 is part of a cage 430 (as shown in FIG. 5A) and includes a pair of catch openings 436 disposed parallelly spaced apart from each other along a vertical axis 30. In one or more examples, when the pluggable module 310 is disposed in the cage 430, the sidewall 342 of the pluggable module 310 is positioned adjacent to the wall 434 of the cage 430 such that the pair of apertures 344 in the sidewall 342 is aligned with the pair of catch openings 436 in the wall 434, and the pair of catches 258 extends through the pair of apertures 344 and engages with the pair of catch opening 436 in the cage 430 to secure the pluggable module 310 to the cage 430. In such examples, the first wall 272 of the handle 252 is disposed adjacent to the wall 434 of the cage 430 and the second wall 274 of the handle 252 is positioned adjacent to the cantilever arm 250 and the sidewall 342 of the pluggable module 310. Further, the first pressing surface 260 of the handle 252 is oriented transverse to a longitudinal axis 15. In one or more examples, the first pressing surface 260 is easily accessible to receive a longitudinal force applied by a user finger positioned along the longitudinal axis 15. Similarly, the second pressing surface 268 is oriented along the longitudinal axis 15. In one or more examples, the second pressing surface 268 is further accessible to receive a lateral force applied by the user finger positioned along a lateral axis 20.

FIG. 5A depicts a perspective view of a portion of an information processing device 506 including a cage 430 having a wall 434 and a pluggable module 310 of FIGS. 4A-4B latched to the wall 434 of the cage 430. FIG. 5B depicts a top view of the portion of the information processing device 506 of FIG. 5A having a chassis 508. In the description hereinafter, FIGS. 5A-5B are described concurrently.

The information processing device 506 includes a chassis 508, a primary system board 518, a cage 430, a pluggable module 310, and a latch assembly 212. The chassis 508 is an enclosure configured to support multiple components of the information processing device 506. The chassis 508 includes a cage 430 defining a bay 432 to receive the pluggable module 310. The cage 430 includes a wall 434 having a catch opening 436 (as shown in FIG. B) to engage with a catch 258 of the latch assembly 212. The primary system board 518 is a mother board of the information processing device 506 mounted on a base of the chassis 508.

In one or more examples, the pluggable module 310 is installed in the bay 432 by slidably inserting the pluggable module 310 along an insertion direction 1, which is parallel to the horizontal axis 10. In some examples, a longitudinal force may be applied on the handle 252 to move the handle 252 in a first lateral direction 40 transverse to the horizontal axis 10 and transition the cantilever arm 250 to the unlatched state, before the pluggable module 310 is slidably inserted into the bay 432. Further, as the pluggable module 310 is slidably inserted into the bay 432, the catch 258 may get aligned with the catch opening 436, causing the handle 252 to move in a second lateral direction 50 opposite the first lateral direction 40 and drive a beam portion 254 of the cantilever arm 250 to automatically extend the catch 258 through the pair of apertures 244 in the sidewall 342 of the pluggable module 310 and engage with the catch opening 436 in the cage 430. Thus, securing the pluggable module 310 to the chassis 508 of the information processing device 506.

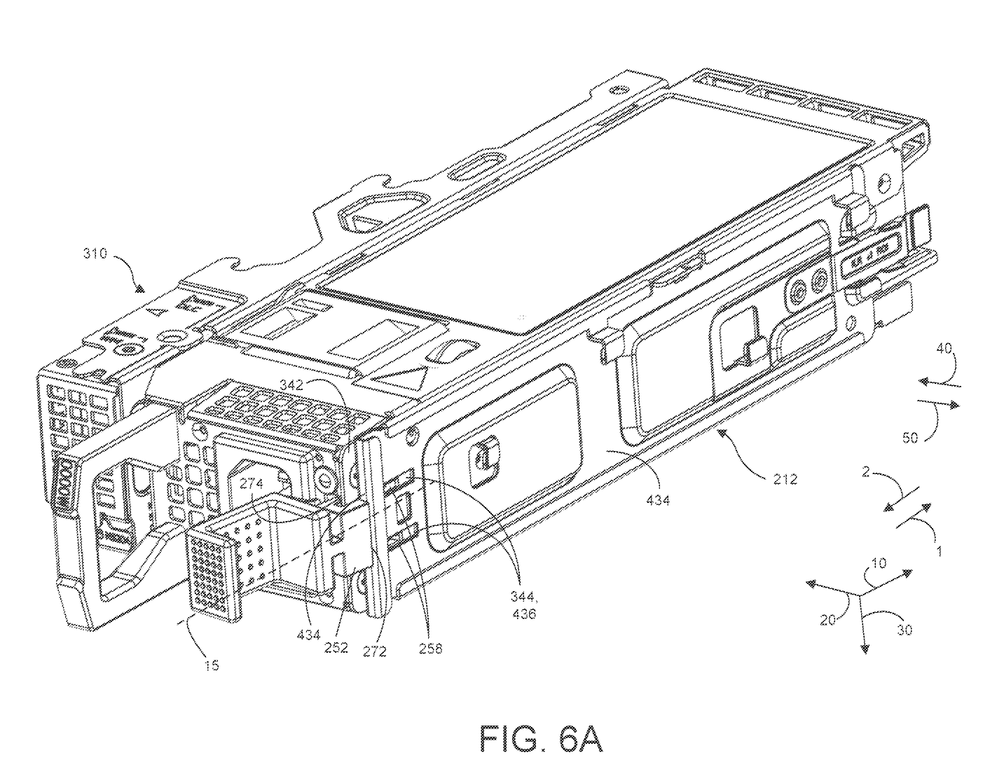

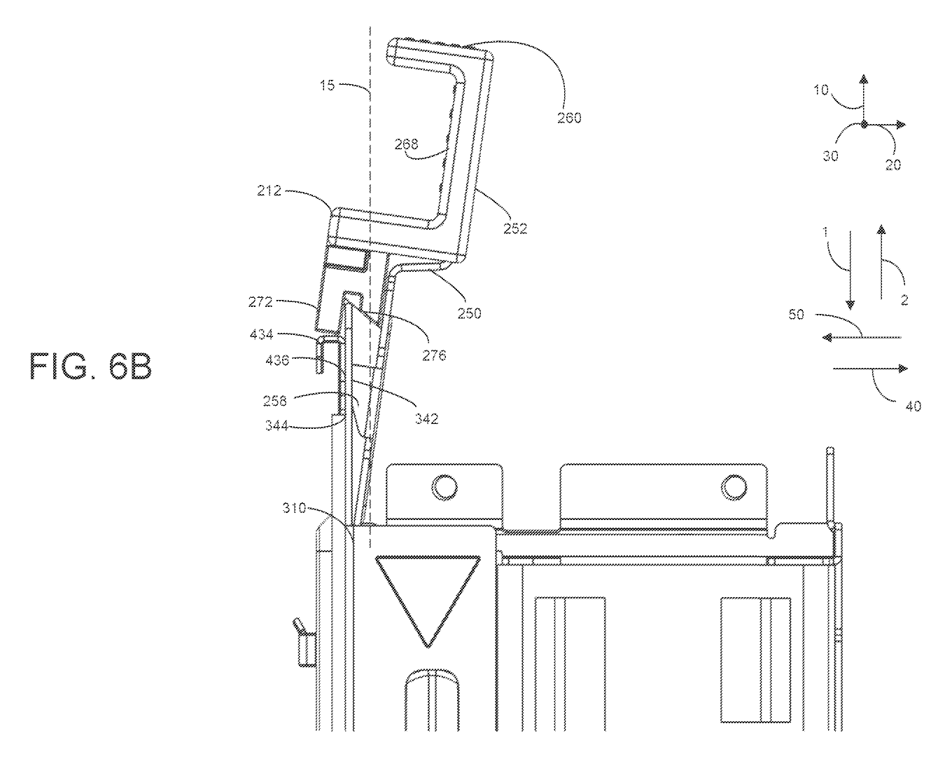

FIG. 6A depicts a perspective view of the pluggable module 310 of FIGS. 4A-4B unlatched from the wall 434 of the cage 430. FIG. 6B depicts a top view of a portion of the pluggable module 310 unlatched from the wall 434 of FIG. 6A. In the description hereinafter, FIGS. 6A-6B are described concurrently for ease of illustration.

In the latched state of the cantilever arm 250, when the longitudinal force is applied on the first pressing surface 260 of the handle 252 by the user’s finger, the handle 252 moves relative to the cantilever arm 250 parallel to the longitudinal axis 15 (e.g., along insertion direction 1). For instance, the handle 252 may slide from a first position to a second position down the cantilever arm 250. In particular, as the handle 252 slides from the first position to the second position, the hole 280 may engage with (e.g., receive) a greater length of the free end portion 255. The handle may further convert this movement of the handle 252 relative to the cantilever arm 250 parallel to the longitudinal axis 15 into movement of the handle 252 relative to the sidewall 342 in the first lateral direction 40. Thus, the longitudinal force applied on the first pressing surface 260 of the handle 252 causes the handle 252 to move in the first lateral direction 40 transverse to the longitudinal axis 15.

In some examples, the second wall 274 of the handle 252 includes a ramp 276 arranged to contact an edge of the sidewall 342 of the pluggable module 310 to convert the longitudinal force into the movement along the first lateral direction 40. For example, the movement of the handle 252 relative to the cantilever arm 250 parallel to the longitudinal axis 15 is converted into movement of the handle 252 relative to the sidewall 342 in the first lateral direction 40 by the ramp 276 sliding along the edge of the sidewall 342. Further, the first wall 272 contacts the wall 434 of the cage 430 and provides the necessary support to the handle 252 when the ramp 276 sliding along the edge of the sidewall 342. In one or more examples, when the handle 252 converts the longitudinal force applied on it into the movement of the handle 252 in the first lateral direction 40, the handle 252 further moves the cantilever arm 250 along the lateral axis 20 and transition the cantilever arm 250 from the latched state to the unlatched state. Accordingly, the cantilever arm 250 moves the catch 258 along the lateral axis 20 to disengage from the catch opening 436 and releases the pluggable module 310 from the cage 430.

FIG. 7 depicts a perspective view of a portion of an information processing device 706 including a cage 430 having a wall 434 and a pluggable module 310 of FIGS. 4A-4B latched to the wall 434 of the cage 430. The information processing device 706 includes a chassis 708, a primary system board 718, a cage 430, a pluggable module 310, and a latch assembly 212. The chassis 708 is an enclosure configured to support multiple components of the information processing device 706. The chassis 708 includes a cage 430 defining a bay 432 to receive the pluggable module 310. The cage 430 includes a wall 434 having a catch opening 436 (as shown in FIG. B) to engage with a catch 258 of the latch assembly 212. The primary system board 718 is a mother board of the information processing device 506 mounted on a base of the chassis 508.

In one or more examples, the pluggable module 310 is uninstalled from the bay 432 by slidably extracting the pluggable module 310 along an extraction direction 2 which is parallel to the horizontal axis 10. In some examples, a longitudinal force may be applied on the handle 252 to move the handle 252 in a first lateral direction 40 transverse to the horizontal axis 10 and transition the cantilever arm 250 from the latched state to the unlatched state. Later, the pluggable module 310, in the unlatched state of the cantilever arm 250, may be pulled out of the information processing device 706 to uninstall the pluggable module 310 from the information processing device 706.

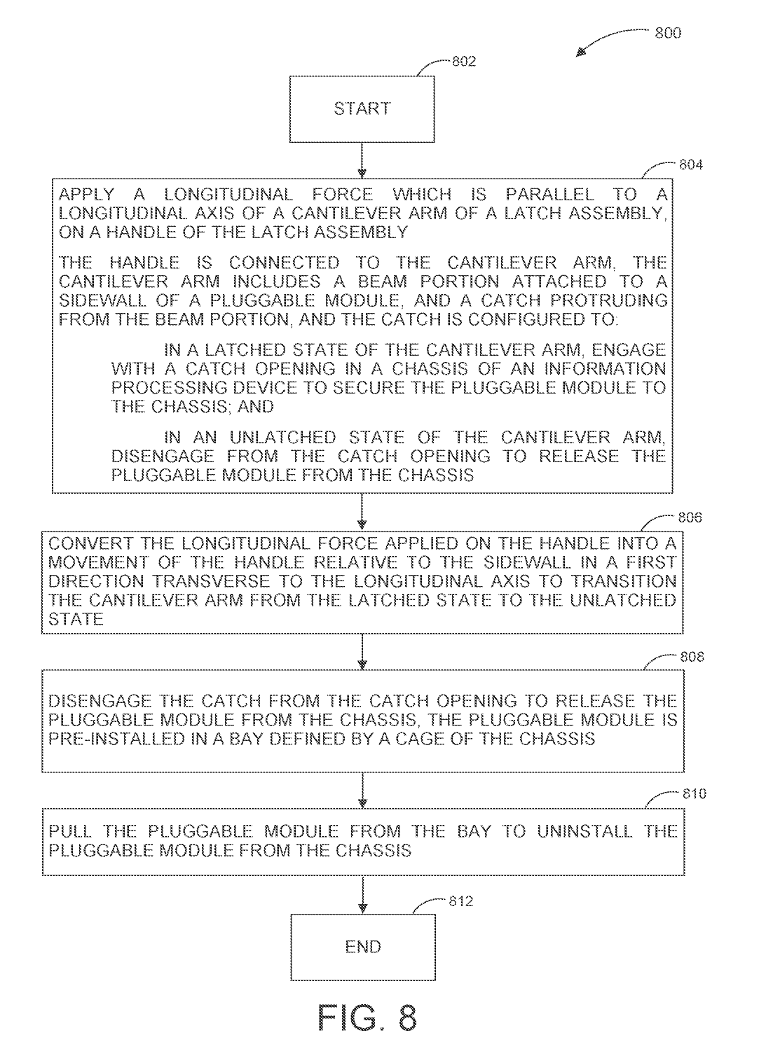

FIG. 8 includes a flowchart showing a method 800 of uninstalling a pluggable module from an information processing device. It may be noted herein that the method 800 is described in conjunction with FIGS. 2A-2E, 3, 4A-4B, 5A-5B, 6A-6B and 7, for example. The method 800 starts at block 802 and continues to block 804.

At block 804, the method 800 includes applying a longitudinal force which is parallel to a longitudinal axis of a cantilever arm of a latch assembly, on a handle of the latch assembly. In some examples, the handle is connected to the cantilever arm. The cantilever arm includes a beam portion attached to a sidewall of a pluggable module, and a catch protruding from the beam portion. In such examples, the catch may be configured to: i) in a latched state of the cantilever arm, engage with a catch opening in a chassis of an information processing device to secure the pluggable module to the chassis, and ii) in an unlatched state of the cantilever arm, disengage from the catch opening to release the pluggable module from the chassis. The method 800 continues to block 806.

At block 806, the method 800 includes converting the longitudinal force applied on the handle into a movement of the handle relative to the sidewall in a first direction transverse to the longitudinal axis to transition the cantilever arm from the latched state to the unlatched state. In some examples, the handle may move relative to the cantilever arm parallel to the longitudinal axis, and a ramp of the handle contacting an edge of the sidewall may convert the movement of the handle into movement of the handle relative to the sidewall in the first direction by the ramp sliding along the edge of the sidewall. The method 800 continues to block 808.

At block 808, the method 800 includes disengaging the catch from the catch opening to release the pluggable module from the chassis. In some examples, the pluggable module may have been pre-installed in a bay defined by a cage of the chassis. The method 800 continues to block 810.

At block 810, the method 800 includes pulling the pluggable module from the bay to uninstall the pluggable module from the chassis. In some examples, a second handle attached to the pluggable module may be pulled while the longitudinal force is still applied on the handle to remove the pluggable module from the chassis. The method 800 ends at block 812.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. A latch assembly for a pluggable module of an information processing device, comprising:
a cantilever arm comprising a beam portion attached to a sidewall of the pluggable module and a catch protruding from the beam portion, the catch configured to:
in a latched state of the cantilever arm, engage with a catch opening in a chassis of the information processing device to secure the pluggable module to the chassis; and
in an unlatched state of the cantilever arm, disengage from the catch opening to release the pluggable module from the chassis; and
a handle connected to the cantilever arm such that, in the latched state, the handle is movable relative to the sidewall in a first direction transverse to a longitudinal axis of the cantilever arm to transition the cantilever arm to the unlatched state, and in the unlatched state, the handle is movable relative to the sidewall in a second direction opposite to the first direction to transition the cantilever arm to the latched state,
wherein the handle is configured to convert a longitudinal force applied to the handle and directed parallel to the longitudinal axis into a movement of the handle relative to the sidewall in the first direction to transition the cantilever arm from the latched state to the unlatched state.

2. The latch assembly of claim 1, wherein the handle comprises a first pressing surface oriented transverse to the longitudinal axis, and wherein the longitudinal force is applied on the first pressing surface.

3. The latch assembly of claim 2, wherein the first pressing surface is oriented perpendicular to the longitudinal axis and parallel to a rear panel of the pluggable module.

4. The latch assembly of claim 2, wherein the first pressing surface comprises friction enhancing features configured to increase a roughness of the first pressing surface.

5. The latch assembly of claim 2, wherein the handle further comprises a second pressing surface oriented transverse to the first pressing surface and configured to receive a lateral force applied directly on the second pressing surface along the first direction to move the handle along the first direction.

6. The latch assembly of claim 5, wherein the second pressing surface is recessed relative to the sidewall by a distance along the first direction of at least 1 cm to facilitate user access to the second pressing surface.

7. The latch assembly of claim 1, wherein the handle further comprises a ramp arranged to contact the sidewall and convert the longitudinal force into the movement of the handle in the first direction.

8. The latch assembly of claim 1, wherein the handle is movably coupled to the cantilever arm such that the handle moves relative to the cantilever arm parallel to the longitudinal axis, and converting the longitudinal force comprises converting movement of the handle relative to the cantilever arm parallel to the longitudinal axis into movement of the handle relative to the sidewall in the first direction.

9. The latch assembly of claim 8, wherein the handle further comprises a ramp arranged to contact an edge of the sidewall and convert the movement of the handle relative to the cantilever arm parallel to the longitudinal axis into movement of the handle relative to the sidewall in the first direction by the ramp sliding along the edge of the sidewall.

10. The latch assembly of claim 8, wherein the handle further comprises a hole engaged with a free end portion of the cantilever arm to movably couple the handle to the cantilever arm.

11. A pluggable module for an information processing device, comprising:
a housing configured to house electronic components of the pluggable module therein and comprising a sidewall having an aperture; and
a latch assembly comprising:
a cantilever arm comprising a beam portion attached to the sidewall and a catch protruding from the beam portion, the catch configured to:
in a latched state of the cantilever arm, extend through the aperture and engage with a catch opening in a chassis of the information processing device to secure the pluggable module to the chassis; and
in an unlatched state of the cantilever arm, disengage from the catch opening to release the pluggable module from the chassis; and
a handle connected to the cantilever arm such that, in the latched state, the handle is movable relative to the sidewall in a first direction transverse to a longitudinal axis to transition the cantilever arm to the unlatched state, and in the unlatched state, the handle is movable relative to the sidewall in a second direction opposite to the first direction to transition the cantilever arm to the latched state,
wherein the handle is configured to convert a longitudinal force applied to the handle and directed parallel to the longitudinal axis into a movement of the handle relative to the sidewall in the first direction to transition the cantilever arm from the latched state to the unlatched state.

12. The pluggable module of claim 11, wherein the handle comprises a first pressing surface oriented transverse to the longitudinal axis, and wherein the longitudinal force is applied on the first pressing surface.

13. The pluggable module of claim 12, wherein the handle further comprises a second pressing surface oriented transverse to the first pressing surface and configured to receive a lateral force applied directly on the second pressing surface along the first direction to move the handle along the first direction.

14. The pluggable module of claim 11, wherein the handle is movably coupled to the cantilever arm such that the handle can move relative to the cantilever arm parallel to the longitudinal axis, and converting the longitudinal force comprises converting movement of the handle relative to the cantilever arm parallel to the longitudinal axis into movement of the handle relative to the sidewall in the first direction.

15. The pluggable module of claim 14, wherein the handle further comprises a ramp arranged to contact an edge of the sidewall and convert the movement of the handle relative to the cantilever arm parallel to the longitudinal axis into movement of the handle relative to the sidewall in the first direction by the ramp sliding along the edge of the sidewall.

16. The pluggable module of claim 11, wherein the pluggable module is one of a power supply unit and a transceiver.

17. An information processing device comprising:
a chassis comprising a cage defining a bay to receive a pluggable module, wherein the cage comprises a wall having a catch opening;
a primary system board mounted to the chassis; and
the pluggable module of claim 11 installed in, or configured to be installed in, the bay such that the catch of the latch assembly is engaged with the catch opening.

18. A method comprising:
applying a longitudinal force which is parallel to a longitudinal axis of a cantilever arm of a latch assembly, on a handle of the latch assembly,
wherein the handle is connected to the cantilever arm, wherein the cantilever arm comprises a beam portion attached to a sidewall of a pluggable module, and a catch protruding from the beam portion, and wherein the catch is configured to:
in a latched state of the cantilever arm, engage with a catch opening in a chassis of an information processing device to secure the pluggable module to the chassis; and
in an unlatched state of the cantilever arm, disengage from the catch opening to release the pluggable module from the chassis;
converting the longitudinal force applied on the handle into a movement of the handle relative to the sidewall in a first direction transverse to the longitudinal axis to transition the cantilever arm from the latched state to the unlatched state;
disengaging the catch from the catch opening to release the pluggable module from the chassis, wherein the pluggable module is pre-installed in a bay defined by a cage of the chassis; and
pulling the pluggable module from the bay to uninstall the pluggable module from the chassis.

19. The method of claim 18, wherein converting the longitudinal force comprises converting movement of the handle relative to the cantilever arm parallel to the longitudinal axis into movement of the handle relative to the sidewall in the first direction.

20. The method of claim 18, wherein the handle comprises a ramp arranged to contact an edge of the sidewall and convert the movement of the handle relative to the cantilever arm parallel to the longitudinal axis into movement of the handle relative to the sidewall in the first direction by the ramp sliding along the edge of the sidewall.
